(19) United States
(12) Patent Application Publication
(10) Pub. No.: US 2026/0368376 A1
(43) Pub. Date: Nov. 19, 2026

(54) APPARATUS AND METHOD FOR OPTIMIZING DATA PROCESSING PATH FOR MULTIMODAL INPUT, AND COMPUTER PROGRAM INCLUDING THE SAME

(71) Applicant: THE DIMENSION COMPANY, Seo-gu (KR)

(72) Inventors: Junhyuk SONG, Yuseong-gu (KR); Re LEE, Hwaseong-si (KR)

(21) Appl. No.: 19/382,751

(22) Filed: Nov. 7, 2025

(30) Foreign Application Priority Data
May 13, 2025 (KR) 10-2025-0061936
Aug. 7, 2025 (KR) 10-2025-0108982
Aug. 7, 2025 (KR) 10-2025-0108983
Aug. 7, 2025 (KR) 10-2025-0108985

(51) Int. Cl. G06F 30/12

(52) U.S. Cl. CPC G06F 30/12

(57) ABSTRACT

An apparatus and method for optimizing a data processing path for multimodal input, and a computer program including the same. An electronic device may include: a memory including at least one instruction; and at least one processor electrically connected to the memory and configured to execute the at least one instruction, wherein the at least one processor may analyze a type of at least one input received from a user, select a data processing unit corresponding to each input type, determine a calling order of the data processing unit based on at least one of an intercorrelation or a priority among each input, call at least one or more data processing units according to the determined processing flow to obtain intermediate data for the at least one input received from the user, and integrate the intermediate data to generate a structured command for creating a CAD (Computer-aided design) representation.

### CROSS-REFERENCE TO RELATED APPLICATIONS

This application claims priority to and the benefit of Korean Patent Application No. 10-2025-0061936, filed on May 13, 2025, Korean Patent Application No. 10-2025-0108982, filed on Aug. 07, 2025, Korean Patent Application No. 10-2025-0108983, filed on Aug. 07, 2025, and Korean Patent Application No. 10-2025-0108985, filed on Aug. 07, 2025, the disclosures of which are incorporated herein by reference in their entirety.

### BACKGROUND

### 1. Field

The present invention relates to a technology for optimizing a data processing path for multimodal input.

### 2. Description of Related Art

Recently, with the advancement of artificial intelligence technology, various attempts have been made to generate three-dimensional (3D) models from text, images, and the like.

As a representative conventional technology, there is a method of applying a diffusion model or a Neural Radiance Fields (NeRF) technology, used for generating two-dimensional images, to a three-dimensional space. However, since these conventional technologies generate results in the form of a polygon mesh or a voxel, they have limitations in that the surface quality of the generated model is uneven, it is difficult to guarantee numerical accuracy, and partial editing or control is difficult. Therefore, it has been difficult to directly utilize these technologies in the production and design fields of actual industrial sites.

Meanwhile, traditional Computer-Aided Design (CAD) software, which is widely used in industrial sites, has the advantage of enabling precise modeling, but requires an expert to manually design all shapes. Due to this, there have been problems in that it takes a long time to learn and master the software, the working time increases exponentially when implementing complex shapes, and design flexibility is reduced due to numerous geometric and numerical constraints.

Accordingly, there is an emerging need for a new technology capable of automatically generating 3D models that are precise and easy to edit enough to be utilized in actual design and production, while allowing even non-experts to implement ideas easily and quickly.

### SUMMARY

An embodiment of the present invention relates to an apparatus for optimizing a data processing path for multimodal input, which can generate a CAD code for a 3D model requested by a user in response to user input.

An embodiment of the present invention relates to an apparatus for optimizing a data processing path for multimodal input that can dynamically determine a processing flow tailored to a user's intent by comprehensively analyzing the user's complex multimodal input, such as text, images, and sketches.

An embodiment of the present invention relates to an apparatus for optimizing a data processing path for multimodal input, which can perform high-accuracy modeling even for specific products not included in pre-trained data by searching and collecting the latest information from external sources in real time and reflecting it in the 3D model generation.

An embodiment of the present invention relates to an apparatus for optimizing a data processing path for multimodal input, which can strengthen the link between design and production by automatically generating and providing Bill of Materials (BOM) information that includes a list of each part constituting the model, its material, and quantity.

An embodiment of the present invention relates to an apparatus for optimizing a data processing path for multimodal input, which, by learning from a dataset that includes the process and intent of a design, can go beyond simple shape transformation to understand the design context and generate a corresponding CAD code.

To solve the problems described above, an apparatus for optimizing a data processing path for multimodal input according to an embodiment of the present invention may comprise at least one processor configured to: analyze a type of at least one input received from a user; select a data processing unit corresponding to each input type; determine a calling order of the data processing unit according to an intercorrelation or priority among the inputs; call at least one or more data processing units according to the determined processing flow to obtain intermediate data; and integrate the intermediate data to generate a structured command for creating a Computer-Aided Design (CAD) representation.

A method for optimizing a data processing path for multimodal input according to an embodiment of the present invention to solve the above problems may comprise the steps of: (a) analyzing a type of at least one input received from a user; (b) selecting a data processing unit corresponding to each input type; (c) determining a calling order of the data processing units based on an intercorrelation or priority between each input; (d) calling at least one or more data processing units according to the determined processing flow to obtain intermediate data; and (e) integrating the intermediate data to generate a structured command for a Computer-Aided Design (CAD) representation.

Furthermore, another embodiment of the present invention may provide a computer-readable storage medium storing instructions that, when executed by a computer, cause the computer to perform the method described above.

An embodiment of the present invention may be an electronic device, comprising: a memory including at least one instruction; and at least one processor electrically connected to the memory and configured to execute the at least one instruction, wherein the at least one processor is configured to: obtain at least one user input; when it is necessary to obtain 3D information from the user input, extract 3D information for the user input via an image module; synthesize the user input and the 3D information to generate a structured command for 3D model generation; and generate a Computer-Aided Design (CAD) representation for the 3D model based on the structured command.

In an embodiment of the present invention, the user input may be at least one of: information about a generated 3D model; information added to the model (such as a visual representation, a sketch, an annotation, etc.); and user-provided input (such as text, 2D data, or 3D data).

In an embodiment of the present invention, the at least one processor may analyze the user input to determine whether it is necessary to obtain 3D information, and according to the determination, may selectively execute the image module when the acquisition of 3D information is necessary.

In an embodiment of the present invention, the at least one processor may analyze the intent of the generation request contained in the user input, and if the intent is to generate a 3D model by maintaining or modifying the geometric shape of specific data input along with the request, the processor may determine that the acquisition of 3D information is necessary.

In an embodiment of the present invention, the structured command may be generated by analyzing the user input according to the rules or a template of a pre-configured database.

In an embodiment of the present invention, the at least one processor may retrieve for information necessary for generating the 3D model from an external source based on the user input, and may additionally use the retrieved information for generating the structured command.

In an embodiment of the present invention, the CAD representation may be at least one of a data structure including design information or a text-based CAD code.

In an embodiment of the present invention, the CAD code may conform to the syntax of a predefined GFL (Geometric Figure Library) code library.

In an embodiment of the present invention, the CAD code may be generated via an artificial intelligence model.

In an embodiment of the present invention, the artificial intelligence model may be trained using a CoT (Chain-of-Thought) dataset that describes the step-by-step generation process of a 3D model.

In an embodiment of the present invention, the at least one processor may visualize the 3D model by rendering the generated CAD representation.

In an embodiment of the present invention, the at least one processor may generate Bill of Materials (BOM) information, which includes a list of each part constituting the 3D model and its quantity, by analyzing the CAD representation.

An embodiment of the present invention may be a method, comprising the steps of: obtaining at least one user input; determining whether obtaining 3D information from the user input is necessary; in response to determining that obtaining the 3D information is necessary, extracting the 3D information for the user input via an image module; synthesizing the user input and the 3D information to generate a structured command for 3D model generation; and generating a CAD representation for the 3D model based on the structured command.

In an embodiment of the present invention, the step of extracting may comprise the steps of: determining, by analyzing the user input, whether it is necessary to obtain 3D information; and selectively executing the image module according to the determination.

In an embodiment of the present invention, the invention may be a computer program recorded on a computer-readable recording medium, configured to be executed in combination with a computer, which is hardware, to perform the method.

An embodiment of the present invention may be an electronic device, comprising: a memory including at least one instruction; and at least one processor electrically connected to the memory and configured to execute the at least one instruction, wherein the at least one processor is configured to receive a text-based command and auxiliary data as input, and to generate a Computer-Aided Design (CAD) representation for the input via a code generation model (a first artificial intelligence model), and wherein the code generation model is pre-trained based on: a first dataset including a first programming code (a high-level source code) and annotation information indicating an execution purpose or intent of the first programming code; and a second dataset comprising a second programming code (a CAD library code, a low-level object code) corresponding to the first programming code.

In an embodiment of the present invention, the text-based command is a natural language text that directs a generation or editing operation of the 3D model to be performed by the code generation model; and the auxiliary data may include at least one of: a target shape of the 3D model, a numerical constraint, part-wise relationship information, and material information.

In an embodiment of the present invention, the CAD representation may be a text-based sequential code comprising functions or parameters that define CAD components.

In an embodiment of the present invention, the first programming code may be a high-level source code that represents the design process of a 3D model, and the second programming code may be a low-level object code that directly defines CAD components.

In an embodiment of the present invention, the first programming code may be a modeling history recorded while a user creates or edits a 3D model in CAD software.

In an embodiment of the present invention, the second programming code may be provided in the form of a library for a general-purpose programming language and may include at least one function and parameter that mathematically defines a shape represented by a Non-Uniform Rational B-Spline (NURBS) surface.

In an embodiment of the present invention, the annotation information may be text data that explains the design purpose or the basis for determination for each step of the first programming code.

In an embodiment of the present invention, the annotation information may be automatically generated by a pre-trained large language model.

In an embodiment of the present invention, the code generation model may be trained by analyzing annotation information associated with each function or command block of the first programming code and, based on the corresponding description, strengthening the correspondence with the CAD library code.

An embodiment of the present invention may be a method, comprising the steps of: receiving a text-based command and auxiliary data as input; and generating a Computer-Aided Design (CAD) representation for the input via a pre-trained code generation model, wherein the code generation model is pre-trained based on: a first dataset including a first programming code and annotation information indicating an execution purpose or intent of the first programming code; and a second dataset comprising a second programming code corresponding to the first programming code.

In an embodiment of the present invention, the text-based command is a natural language text that directs a generation or editing operation of a 3D model, and the auxiliary data may include at least one of a target shape of the 3D model or a numerical constraint.

In an embodiment of the present invention, the first programming code may be a modeling history recorded while a user creates or edits a 3D model in CAD software.

In an embodiment of the present invention, the second programming code may be provided in the form of a library for a general-purpose programming language and may include at least one function and parameter that mathematically defines a shape represented by a Non-Uniform Rational B-Spline (NURBS) surface.

In an embodiment of the present invention, the code generation model may be trained by analyzing annotation information associated with each function or command block of the first programming code and, based on the corresponding description, strengthening the correspondence with the CAD library code.

An embodiment of the present invention may be a computer program recorded on a computer-readable recording medium, configured to be executed in combination with a computer, which is hardware, to perform the method.

The disclosed technology may have the following effects. However, it is not to be understood that the scope of rights of the disclosed technology is limited thereby, as it is not meant that a specific embodiment must include all of the following effects or only those effects.

An apparatus for optimizing a data processing path for multimodal input according to an embodiment of the present invention can generate a CAD code for a 3D model requested by a user in response to user input.

An apparatus for optimizing a data processing path for multimodal input according to an embodiment of the present invention can generate a CAD code for a 3D model requested by a user in response to user input.

An apparatus for optimizing a data processing path for multimodal input according to an embodiment of the present invention can perform high-accuracy modeling even for specific products not included in pre-trained data by searching and collecting the latest information from external sources in real time and reflecting it in the 3D model generation.

An apparatus for optimizing a data processing path for multimodal input according to an embodiment of the present invention can strengthen the link between design and production by automatically generating and providing Bill of Materials (BOM) information that includes the list, material, and quantity of each part constituting the model.

An apparatus for optimizing a data processing path for multimodal input according to an embodiment of the present invention, by learning from a dataset that includes the process and intent of a design, can go beyond simple shape transformation to understand the design context and generate a corresponding CAD code.

### BRIEF DESCRIPTION OF THE DRAWINGS

FIG. 1 is a diagram illustrating an interaction with an external system according to an embodiment of the present invention.

FIG. 2 is a diagram illustrating a physical configuration according to an embodiment of the present invention.

FIG. 3 is an internal functional block diagram of the electronic device (130) according to an embodiment of the present invention.

FIG. 4 is a block diagram of a structured command according to an embodiment of the present invention.

FIG. 5 is a block diagram illustrating a method for generating a CAD representation according to an embodiment of the present invention.

FIG. 6 is a diagram illustrating a training process of a code generation model according to an embodiment of the present invention.

FIGS. 7a and 7b are diagrams illustrating a processing method of an image module according to an embodiment of the present invention.

FIGS. 8a and 8b are diagrams illustrating a sequential process according to an embodiment of the present invention.

FIG. 9 is a diagram illustrating a parallel process according to an embodiment of the present invention.

### DETAILED DESCRIPTION

The description of the present invention is merely for illustrative purposes of structural and functional aspects, and therefore, the scope of the present invention should not be construed as being limited to the embodiments described herein. That is, since the embodiments may be subject to various modifications and may have various forms, the scope of the present invention should be understood to include equivalents that can realize the technical ideas thereof. Furthermore, since it is not intended that the objects or effects presented in the present invention must be included in their entirety or exclusively in any particular embodiment, the scope of the present invention should not be understood as being limited thereto.

Meanwhile, the meanings of terms described in the present application should be understood as follows

Terms such as "first" and "second" are used to distinguish one component from another, and the scope of rights should not be limited by these terms. For example, a first component may be referred to as a second component, and similarly, a second component may also be referred to as a first component.

When a component is described as being "connected" to another component, it should be understood that it can be directly connected to the other component, but that other components may exist in between. On the other hand, when a component is described as being "directly connected" to another component, it should be understood that no other components exist in between. Meanwhile, other expressions for describing the relationships between components, such as "between" and "directly between" or "adjacent to" and "directly adjacent to," should be interpreted in the same manner.

Singular expressions should be understood to include plural expressions unless the context clearly indicates otherwise, and terms such as "comprising" or "having" are intended to specify the presence of the stated features, numbers, steps, operations, components, parts, or combinations thereof, and should not be understood to preclude the presence or addition of one or more other features, numbers, steps, operations, components, parts, or combinations thereof.

In each of the steps, identification symbols (e.g., a, b, c, etc.) are used for convenience of explanation and do not describe the order of the steps, and each step may occur in a different order from that specified unless a specific order is explicitly stated in the context. That is, the steps may occur in the same order as specified, may be performed substantially simultaneously, or may be performed in the reverse order.

The present invention may be implemented as a computer-readable code on a computer-readable recording medium, and the computer-readable recording medium includes any kind of recording device on which data that can be read by a computer system is stored. Examples of the computer-readable recording medium include ROM, RAM, CD-ROM, magnetic tape, floppy disk, and optical data storage devices, and also include implementations in the form of a carrier wave (e.g., transmission over the Internet). Furthermore, the computer-readable recording medium may be distributed over computer systems connected via a network, so that the computer-readable code can be stored and executed in a distributed manner.

Unless otherwise defined, all terms used herein have the same meaning as commonly understood by one of ordinary skill in the art to which the present invention pertains. Generally used and predefined terms in dictionaries should be interpreted as having a meaning consistent with their meaning in the context of the relevant art and should not be construed as having an idealized or excessively formal meaning unless explicitly defined in the present application.

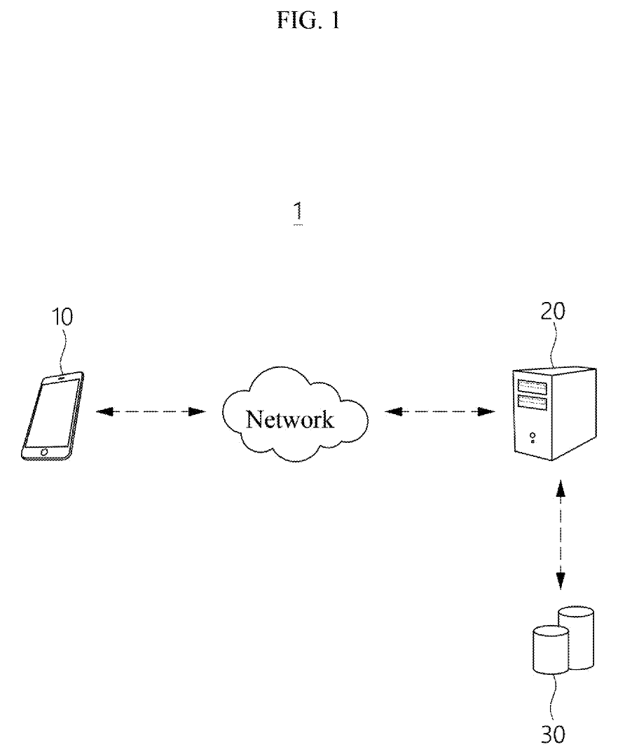

FIG. 1 is a diagram illustrating a system according to an embodiment of the present invention. Referring to FIG. 1, the system (100) may include a user terminal (110), an electronic device (130), and a database (150).

The user terminal (110) may be implemented as a smartphone or a wearable device for checking data generated via the electronic device (130) and metadata obtained by analyzing the data, but is not limited thereto and may also be implemented as various other devices such as a tablet PC. The user terminal (110) may be connected to the electronic device (130) through a network, and a plurality of user terminals (110) may be simultaneously connected to the electronic device (130).

The electronic device (130) may include an agent-based three-dimensional model generation device. The electronic device (130) may be provided included in a computer-readable recording medium, by tangibly embodying a program of instructions for implementing it. In other words, the electronic device (130) may be implemented in the form of program commands that can be executed through various computer means and may be recorded on a computer-readable recording medium. Furthermore, the electronic device (130) may consist of a computer program that sequentially or non-sequentially performs operations of obtaining a user input, extracting 3D information for the user input through an image module when necessary, generating a structured command for 3D model generation using the information, and generating a CAD representation for CAD model creation based on the structured command, and the computer program may be stored on a computer-readable recording medium. Additionally, the electronic device (130) may be composed of a computer program that sequentially or non-sequentially performs the operations of analyzing the type of at least one input received from a user, selecting a data processing unit corresponding to each input type, determining the calling order of the data processing units based on at least one of intercorrelation or priority among each input, calling at least one or more data processing units according to the determined processing flow to obtain intermediate data for the at least one input received from the user, and integrating the intermediate data to generate a structured command for creating a CAD (Computer-Aided Design) representation, and the computer program may be stored on a computer-readable recording medium. Moreover, the electronic device (130) may be constituted by a computer program that sequentially or non-sequentially performs the operations of receiving a text-based command and auxiliary data as input, and generating a CAD (Computer-Aided Design) representation for the input through a code generation model (a first artificial intelligence model), and the computer program may be stored on a computer-readable recording medium.

The database (150) may be a storage device that stores various information generated during the operation of the electronic device (130).

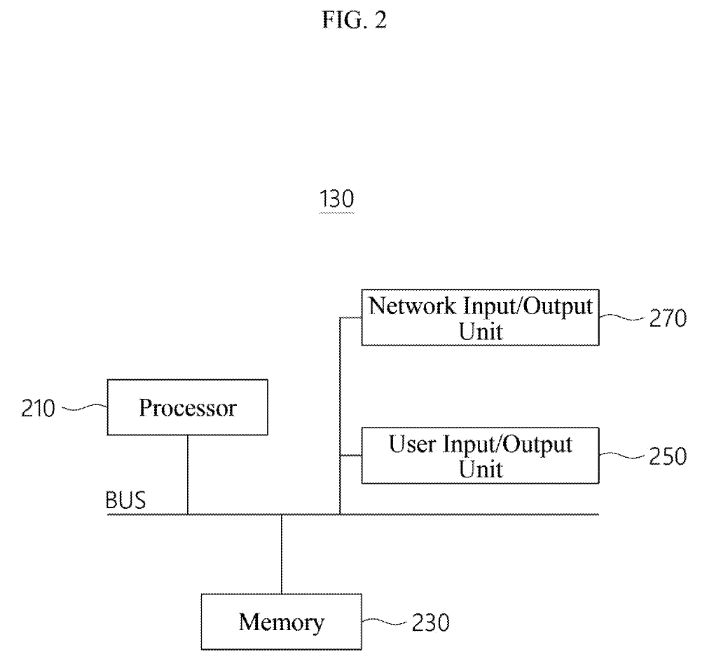

FIG. 2 is a diagram illustrating a physical configuration of an electronic device (130) according to an embodiment. Referring to FIG. 2, the electronic device (130) may be implemented to include a processor (210), a memory (230), a user input/output unit (250), and a network input/output unit (270)

The processor (210) may include at least one processor, at least a portion of which is implemented to provide different functions. The processor (210) may control the overall operation of the electronic device (130) and may be electrically connected to the memory (230), the user input/output unit (250), and the network input/output unit (270) to control the data flow therebetween. The processor (210) may be implemented as a Central Processing Unit (CPU) of the electronic device (130). According to an embodiment, the processor (210) may include a main processor (e.g., a central processing unit or an application processor) or an auxiliary processor (e.g., a graphics processing unit, a neural processing unit (NPU), an image signal processor, a sensor hub processor, or a communication processor) that can operate independently of or in conjunction with the main processor. For example, when the electronic device (130) includes a main processor and an auxiliary processor, the auxiliary processor may be configured to use less power than the main processor or to be specialized for a designated function. The auxiliary processor may be implemented separately from, or as a part of, the main processor. The auxiliary processor may, for example, control at least a portion of the functions or states related to at least one of the components of the electronic device (130) on behalf of the main processor while the main processor is in an inactive (e.g., sleep) state, or together with the main processor while the main processor is in an active (e.g., application execution) state. According to an embodiment, an auxiliary processor (e.g., an image signal processor or a communication processor) may be implemented as part of another functionally related component. According to an embodiment, an auxiliary processor (e.g., a neural processing unit) may include a hardware structure specialized for processing an artificial intelligence model. An artificial intelligence model may be generated through machine learning. Such learning may be performed, for example, on the electronic device (130) itself where the artificial intelligence model is executed, or it may be performed via a separate server. A learning algorithm may include, for example, supervised learning, unsupervised learning, semi-supervised learning, or reinforcement learning, but is not limited to the examples described above. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more thereof, but is not limited to the examples described above. In addition to or as an alternative to a hardware structure, the artificial intelligence model may include a software structure. Meanwhile, the operations of the electronic device (130) described hereinafter may be understood as operations of the processor (210).

The memory (230) may include an auxiliary storage device, which is implemented as a non-volatile memory such as a Solid State Drive (SSD) or a Hard Disk Drive (HDD) and is used to store the overall data required for the electronic device (130), and may also include a main storage device implemented as a volatile memory such as Random Access Memory (RAM). Furthermore, the memory (230) may include a plurality of instructions for directing the operations of the processor (210) to implement functions provided by a service. In this case, the processor (210) may include a software server that executes the functions provided by the service based on the plurality of instructions stored in the memory (230).

The user input/output unit (250) may include an environment for receiving user input and an environment for outputting specific information to a user. For example, the user input/output unit (250) may include an input device comprising an adapter such as a touch pad, a touch screen, a virtual keyboard, or a pointing device, and an output device comprising an adapter such as a monitor or a touch screen. In an embodiment, the user input/output unit (250) may correspond to a computing device accessed via a remote connection, and in such a case, the electronic device (130) may function as a server.

The network input/output unit (270) includes an environment for connecting with an external device or system via a network and may include, for example, an adapter for communication such as a Local Area Network (LAN), a Metropolitan Area Network (MAN), a Wide Area Network (WAN), and a Value Added Network (VAN).

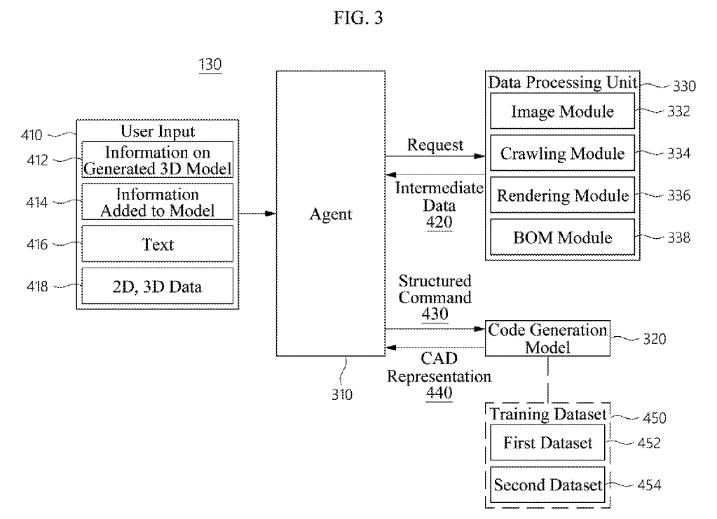

FIG. 3 is an internal functional block diagram of an electronic device (130) according to an embodiment of the present invention. Hereinafter, for convenience of description, an agent (310) or each module may be described as the subject of an operation, but this may be an operation performed by at least one processor (210) included in the electronic device (130) executing instructions stored in the memory (230). Referring to FIG. 3, the electronic device (130) may include an agent (310), a code generation model (320), and a data processing unit (330).

Describing the overall operation of the present invention from the perspective of an AI agent, the agent (310) may serve as an orchestrator that oversees the entire data processing flow. For example, the agent (310) may be implemented based on a large language model (LLM), and it interprets the user's input to select a specific module within the data processing unit (330) necessary for achieving a goal and determines the calling order. In this case, individual data processing modules such as the image module (332) and the crawling module (334) can be regarded as respective 'tools' used by the AI agent, and details thereof will be described later.

In an embodiment, the agent (310) may itself be implemented to include one or more artificial intelligence models. For example, the agent (310) may be configured as an ensemble of multiple artificial intelligence models dedicated to specific sub-tasks, such as a natural language processing (NLP) model that analyzes the natural language of user input, an image classification model that identifies the type of an image, and a reinforcement learning-based scheduling model that determines the calling order of each module. In another embodiment, the agent (310) may also be implemented as a single large language model (LLM) capable of performing all of these complex analysis, judgment, and control functions.

The agent (310) may obtain user input (410) from a user. As shown in the drawing, the user input (410) may be a multimodal input that includes various forms of data, such as information about a previously generated 3D model (412), added information like a sketch or annotation added to the model by the user (414), natural language text (416), or 2D/3D data (418). The agent (310) may perform a control role of comprehensively analyzing the type and content of the received user input (410) to determine the overall processing flow required for 3D model generation.

In an embodiment, the agent (310) may extract keywords from text included in the user input and identify the format of the accompanying data. This is for the purpose of selecting an optimal processing module by understanding the role and meaning of the various data included in the multimodal input. For example, the agent (310) may recognize the need to execute the crawling module (334) by extracting a specific product name such as "Galaxy S24" as a keyword, and if the format of the input data is an image or a sketch, it may prepare for the execution of the image module (332). Through this analysis process, the agent (310) can establish the basic information for determining the processing flow, which will be described later.

In another embodiment, when the agent (310) determines that it is difficult to generate a structured command because the user input is ambiguous or insufficient, it may perform an interactive query to request additional information from the user. For example, if a user inputs "make me a cool chair," the agent (310) may determine that the criterion for the expression 'cool' is ambiguous and may present questions to the user requesting specific information, such as "What style (e.g., modern, classic) would you like?" or "Do you have a preferred material?". Through such an interactive query, the agent (310) can clarify the user's requirements through interaction with the user and ultimately generate a 3D model that better aligns with the user's intent.

In another embodiment, the agent (310) may generate or optimize a structured command by referencing a pre-stored user profile. The user profile may include a user's past work history, frequently used design styles, preferred materials, or design specifications that must be adhered to in a specific project. For example, if a specific user's profile records a 'preference for minimalist style,' even if the user simply inputs "make me a table," the agent (310) may reference this to generate a structured command that includes design parameters for a minimalist style. Through this, it is possible to increase work efficiency and satisfaction by automating the creation of customized 3D models tailored to the characteristics of each user or project.

Furthermore, the agent (310) may request the data processing unit (330) to perform a specific task based on the analysis result. The data processing unit (330) includes at least one processing module, and may include, for example, an image module (332) for extracting 3D information from an image, a crawling module (334) for retrieving information from external sources, a rendering module (336) for visualizing a CAD representation as a 3D model, or a BOM module (338) for generating a bill of materials. After performing the requested task, the data processing unit (330) may transmit the resulting intermediate data (420) to the agent (310).

Here, the intermediate data may be at least one of: geometric shape information obtained from the image module, text-based specification information obtained from the crawling module, and semantic information extracted from the user input text. Furthermore, in an embodiment, this intermediate data (420) may be managed in the form of a structured data object. For example, in addition to raw data generated from a processing module, such a data object may include metadata indicating a processing priority of the corresponding data or its relationship with other data. By managing the intermediate data in such a structured manner, the agent (310) can efficiently integrate heterogeneous data from various sources and, based thereon, establish a clear basis for generating the final structured command.

In an embodiment, the agent (310) may analyze the user input to determine whether obtaining 3D information is necessary, and based on this determination, may selectively execute the image module when the acquisition of 3D information is necessary. This is to prevent performing unnecessary computations for every request and to use system resources efficiently. For example, when a user makes a conceptual generation request, such as "create a cylinder made of metal," the agent may determine that obtaining 3D information is unnecessary and may not execute the image module (332). On the other hand, for a request that references a specific shape, as will be described later, the agent executes the image module (332) to obtain the necessary 3D information.

In an embodiment, the agent (310) may analyze the intent of a generation request contained in the user input, and if the intent is to generate a 3D model by maintaining or modifying the geometric shape of specific data input therewith, the agent may determine that the acquisition of 3D information is necessary. Here, 'maintaining the shape' may include a case in which a sketch or an image provided by a user is restored into a 3D model as is. Furthermore, 'modifying the shape' may include a case in which a new 3D model is generated by modifying specific parameters based on the geometric features of the input data, such as "make it similar to this chair image, but increase the leg length by 10 cm". Through such a determination, the agent (310) can fulfill a user's complex and specific requirements.

Furthermore, the agent (310) may generate a structured command (430) in a format understandable by the code generation model (320) by synthesizing the initial user input (410) and the intermediate data (420) received from the data processing unit (330).

The structured command (430) is transmitted to the code generation model (320). The code generation model (320) may be a pre-trained artificial intelligence model based on a training dataset (450). The training dataset (450) may include a first dataset (452) comprising a first programming code and annotation information, and a second dataset (454) comprising a second programming code corresponding to the first programming code. Here, the annotation information may include the execution purpose or intent of the code, which will be described in detail later.

The code generation model (320) generates a CAD representation (440), which is a final output, based on the received structured command (430) and transmits it to the agent (310). The agent (310) may control subsequent processing, such as sending this CAD representation (440) to the rendering module (336) for visualization or to the BOM analysis module (338) to generate additional information.

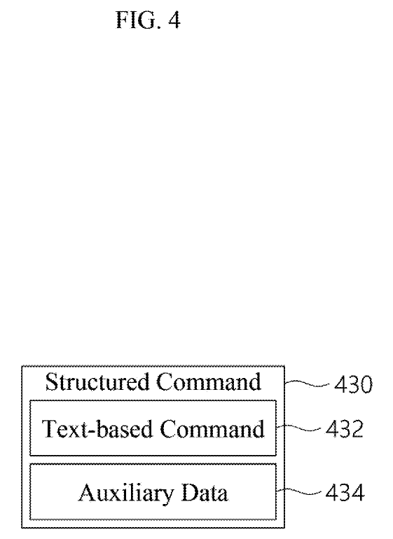

FIG. 4 is a block diagram of a structured command according to an embodiment of the present invention. Referring to FIG. 4, the structured command may include a text-based command (432) and auxiliary data (434). This may be a final information packet processed by the AI agent (310) by synthesizing a user's complex requirements and various intermediate data so that the code generation model (320) can clearly understand and execute it.

In an embodiment, the structured command may follow a data structure (schema) defined by the rules or a template of a pre-configured database. These rules or the template define required fields that must be included in the command, the data format of each field, and default values of parameters, so that the structured command (430) can be consistently processed by the code generation model (320). The AI agent (310) analyzes the user's input and completes the final structured command (430) by filling in the value of each field in accordance with this predefined data structure.

Furthermore, if the user's input is insufficient or ambiguous, making it impossible to fill all the required fields defined by the rules or template, the agent (310) may generate the structured command (430) by automatically filling the corresponding fields with a preset default value or a value with the highest probability. Through this, even if the user does not provide all information in detail, the system can generate a complete command to ensure stable operation.

In an embodiment, the structured command is a prompt provided to an artificial intelligence model for generating a CAD representation, and may include at least one of: a target shape of the 3D model, a numerical constraint, part-wise relationship information, and material information. This may be the result of the agent (310) translating the user's various requirements into a language that the code generation model (320) can clearly understand.

For example, if a user inputs, "Make it similar to a Galaxy S24, but change only the back material to matte black," the agent (310) may first obtain, as intermediate data, precise dimensions (width, height, thickness) and component layout information (e.g., camera) of the corresponding model from an external source based on the keyword 'Galaxy S24'. Subsequently, the agent (310) may synthesize the obtained intermediate data and the user's additional request ('back material: matte black') to generate a structured command (430) that includes the following information.

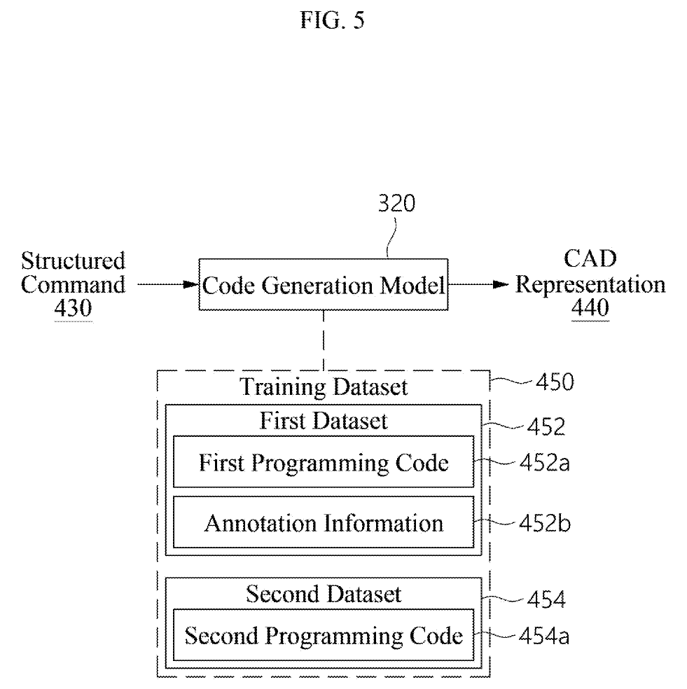

FIG. 5 is a block diagram illustrating a method for generating a CAD representation according to an embodiment of the present invention. Although the operation of the code generation model (320) shown in FIG. 5 is described with the model as the subject for convenience of explanation, it may actually be performed by at least one processor (210) included in the electronic device (130).

Referring to FIG. 5, the code generation model (320) may receive the structured command (430) generated from the agent (310) as input. The code generation model (320) may interpret the received structured command (430) to generate and output a CAD representation (440), which is the corresponding final output. In this case, the CAD representation (440) is not limited to a specific format. In an embodiment, the CAD representation (440) may be a text-based CAD code composed of functions and parameters that mathematically define items such as a NURBS surface. In another embodiment, the CAD representation (440) may be a data structure that includes design information defining the components of a three-dimensional model and their relationships, and may include, for example, a data structure in which GFL (Geometric Figure Library) objects are configured in a tree structure. More specifically, a case of generating a chair model may be taken as an example. In this case, the CAD representation may be generated as a hierarchical data structure in which a top-level object (Root Object) representing the entire 'chair' exists, and component objects such as a 'seat', a 'backrest', and 'legs' are connected as child nodes thereunder. At this time, each component object may have shape information defined in the GFL and unique parameters (e.g., dimensions, material, etc.). As such, the present invention can enhance flexibility by generating various forms of CAD representations.

To this end, the code generation model (320) may be pre-trained based on a training dataset (450). The training dataset (450) may include a first dataset (452) and a second dataset (454).

The first dataset (452) constitutes the training input for the model and may include a first programming code (452a) and annotation information (452b). Here, the first programming code (452a) corresponds to a high-level source code (e.g., a modeling history in CAD software) that represents the design process of a 3D model, and the annotation information (452b) may correspond to CoT (Chain-of-Thought) data that explains the design intent or basis for determination for each step of the first programming code (452a). In other words, the first programming code (452a) is a modeling history recorded during the process in which a user creates or edits a 3D model in CAD software, and the annotation information (452b) may include the design intent or basis for determination thereof. For example, if the first programming code (452a) is a code corresponding to "create a cylinder, add a smaller cylinder to the end, round the top edge," the corresponding annotation information (452b) may include text that explains the design intent of each step, such as "create the body of a water bottle," "create the bottleneck section," and "improve the usability of the part where the user's lips touch," respectively.

Here, the annotation information (452b) may be generated in various ways. In an embodiment, the annotation information (452b) may be automatically generated by a separate large language model (LLM) that has been trained to analyze the first programming code (452a) and infer its intent. This can be used to efficiently build a training dataset from a large amount of modeling history.

In another embodiment, the annotation information (452b) may also be directly input as text by a user who is a design expert. By thus combining the automatic generation method and the manual input method, it is possible to secure both the quantity and quality of the training data and, as needed, to maximize the performance of the code generation model (320) by reflecting the sophisticated knowledge of experts in the data.

The second dataset (454) constitutes the data corresponding to the 'correct answer' during model training and may include a second programming code (454a). The second programming code (454a), as the result finally implemented by the design process of the first programming code (452a), may correspond to a low-level object code (e.g., a GFL code) capable of representing items such as a NURBS surface. Specifically, the second programming code may be provided in the form of a library for a general-purpose programming language and may include at least one function and parameter that mathematically defines a shape represented by a Non-Uniform Rational B-Spline (NURBS) surface. For example, the second programming code (454a) corresponding to the first programming code (452a) described above, "create cylinder, add bottleneck, process edge," may take the form of a GFL code. In other words, the second programming code (454a) may be composed of a series of function calls and parameter values that mathematically describe the precise shape of the 3D model. As such, the code generation model (320) may be trained to generate a 'correct answer' code like this by observing the process and intent of the first dataset (452), which will be described in detail later.

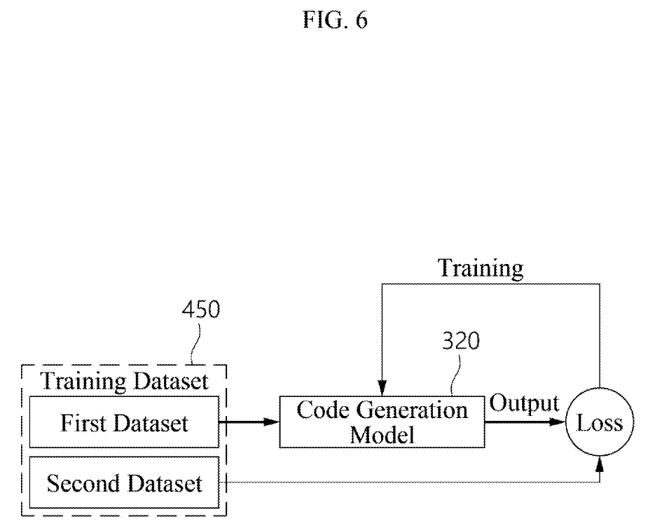

FIG. 6 is a diagram illustrating a training process of the code generation model (320) according to an embodiment of the present invention. Referring to FIG. 6, training of the code generation model (320) may be performed by generating a prediction result (output) for a specific training input, calculating a loss between the prediction result and a target value, and updating internal parameters by receiving the calculated loss as feedback.

In an embodiment, as shown in FIG. 6, the training dataset (450) may include a first dataset (452) and a second dataset (454) as a single pair. In this case, the code generation model (320) may be trained to minimize the difference (Loss) between the two by receiving the first dataset (452) as input and considering the second dataset (454) as the ground truth.

In another embodiment, the code generation model (320) may be trained using a 'structured command' generated by an AI agent through actual user input as the training input, and a corresponding second dataset (454) as the correct answer. This enables the performance of the model to be progressively improved by continuously utilizing data generated in an actual use environment for training. In this case, the 'structured command' may be used as is, or it may be converted into the format of the first dataset and used for training.

In another embodiment, for a CAD representation (output) generated by the code generation model (320) from a 'structured command' input, the model may be provided with a reward score as a target value, instead of a predetermined 'correct answer'. The reward score may be calculated based on factors such as the design quality of the generated CAD representation, numerical accuracy, or user satisfaction feedback, and the code generation model (320) may be trained to obtain a higher reward score.

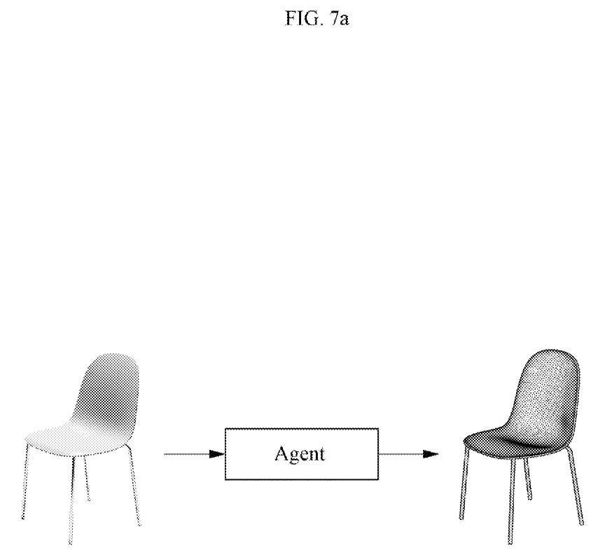

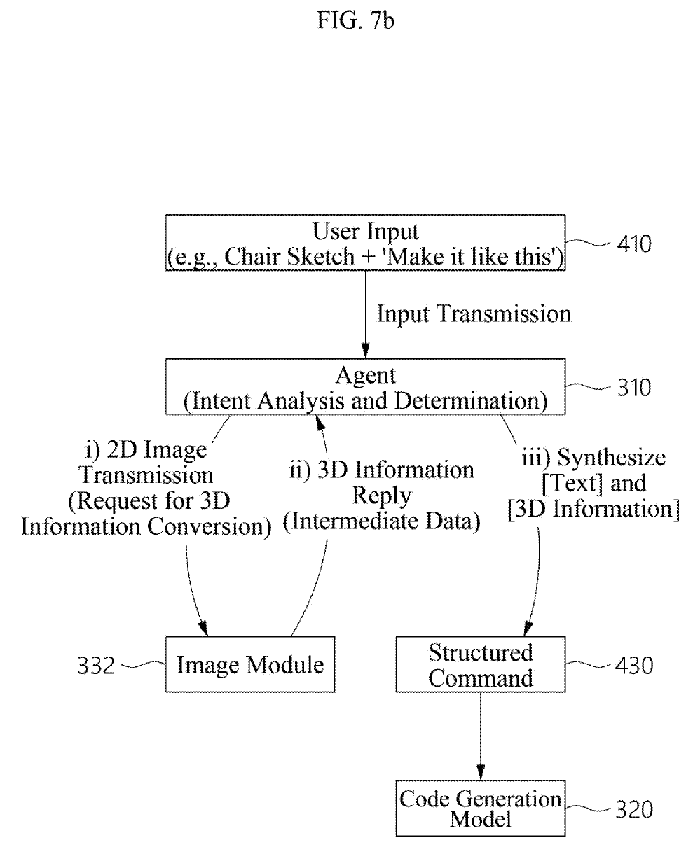

FIGS. 7A and 7B are diagrams illustrating a processing method of an image module according to an embodiment of the present invention.

Referring to FIG. 7A, a user may, for example, provide user input (410) that includes a 2D image, such as a 'chair sketch,' and text, such as 'make it like this.' The agent (310) may analyze the received input and determine that it is necessary to convert the 2D image into 3D information.

Accordingly, the agent (310) may first transmit the 2D image to the image module (332) to request its conversion into 3D information. Here, the role of the image module (332) is to extract the geometric and structural features necessary for 3D model generation from the two-dimensional visual data. For example, the image module (332) may analyze the contours of the sketch, the proportions of major parts, and the sense of depth, and convert them into quantified 3D information.

The image module (332) may return the extracted 3D information to the agent (310) as intermediate data. Finally, the agent (310) may synthesize the user's initial text command with the 3D information received from the image module to ultimately generate a structured command (430) and transmit it to the code generation model (320).

Referring to FIG. 7B, a three-dimensional model (e.g., a chair) having a specific style (e.g., a solid form) may be provided as input to the agent (310). The agent (310) may receive this input image and perform internal processing, such as extracting shape information via the image module (332) as described in FIG. 7A, and generating a structured command based thereon to be transmitted to the code generation model (320). Through this, the agent (310) can ultimately generate a three-dimensional CAD model that precisely implements the shape of the original image.

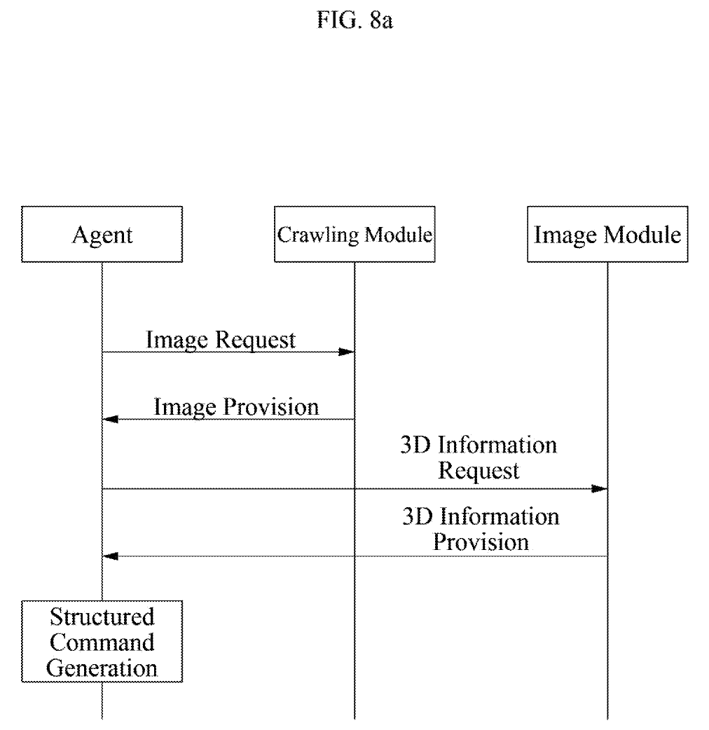

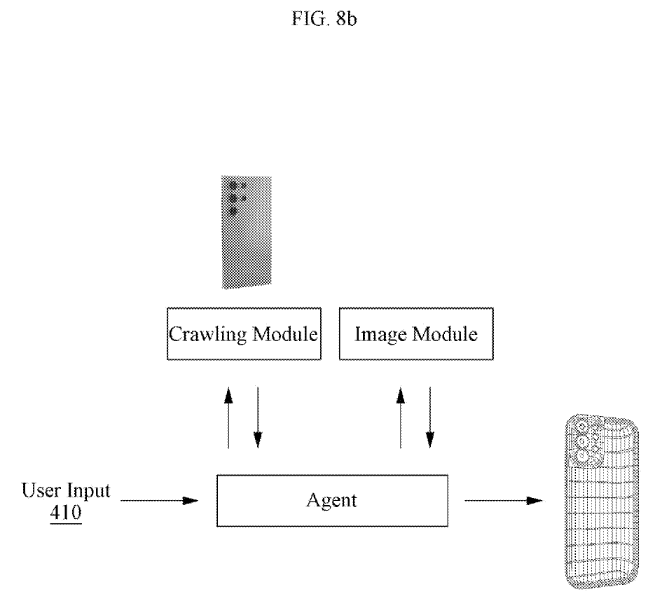

FIGS. 8A and 8B is a diagram illustrating a sequential process according to an embodiment of the present invention.

Referring to FIG. 8A, the agent (310) may determine the calling order of the data processing units based on at least one of an intercorrelation or a priority among each input. Specifically, when a data dependency exists between a plurality of data processing units, the agent (310) may determine to provide the intermediate data obtained from the execution result of a preceding data processing unit as an input to a succeeding data processing unit.

For example, the agent (310), upon receiving an input from a user including a specific product name (e.g., "Galaxy S24"), may determine that visual information of the corresponding product is necessary. In this case, the agent (310) first sends an image request to the crawling module (334). The crawling module (334) may retrieve the corresponding image from an external source (e.g., the web) and provide the retrieved image to the agent (310) as intermediate data.

Subsequently, the agent (310) sends the image received from the crawling module (334) as input to the image module (332) to request 3D information. The image module (332) may analyze the received image to extract geometric shape information, provide the extracted 3D information to the agent (310) as another piece of intermediate data, and the agent (310) may synthesize the intermediate data obtained through this sequential process to generate a structured command. In other words, the preceding data processing unit may be the crawling module, and the succeeding data processing unit may be the image module.

Referring to FIG. 8B, the agent (310), upon receiving user input (410), may collect the necessary intermediate data by interacting with the crawling module (334) and the image module (332). Specifically, the agent (310) may first perform a first step of calling the crawling module (334) to obtain an image of a specific product. Subsequently, it may perform a second step of calling the image module (332) using the image, which is the result of the first step, as input to extract geometric features. As such, since the operations of the two modules have a data dependency, they may necessarily be performed sequentially.

Afterward, the agent (310) may generate a structured command based on the obtained information and transmit it to a code generation model (not shown) to obtain a CAD representation (e.g., code). Subsequently, the agent (310) may control the generation of a final three-dimensional model (the wireframe smartphone shown on the right) by sending the obtained CAD code back to a rendering module (not shown). Therefore, the agent (310) in FIG. 8B conceptually represents the role of an orchestrator that oversees the entire process of generation request, data reception, and subsequent processing control.

Furthermore, the agent (310) can enhance the generation capability of the code generation model by performing Retrieval-Augmented Generation (RAG) technology. The aforementioned process of obtaining the latest information from an external source via the crawling module (334) corresponds to the 'Retrieval' step of RAG.

Subsequently, the agent (310) performs the 'Augmented Generation' step. That is, the agent (310) generates a structured command by combining the user's original request (e.g., "Make a Galaxy S24") and the latest information obtained through the search (e.g., 'height: 147.0 mm', 'material: Armor Aluminum', etc.) into a single, complete prompt.

This augmented structured command is transmitted to the code generation model, enabling the model to generate an accurate and fact-based CAD representation even for content not included in the pre-trained data. Through this, the system can ensure both extensibility for the latest information and the accuracy of the output.

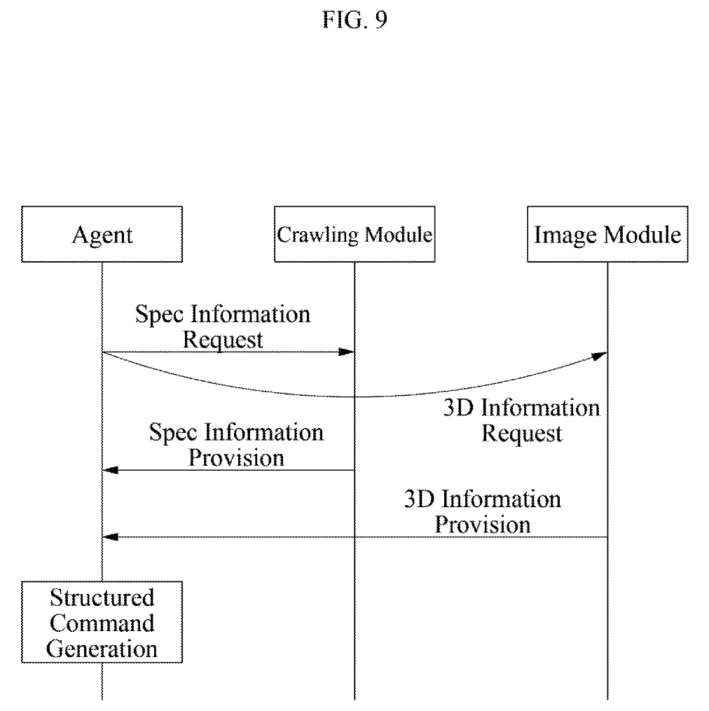

FIG. 9 is a diagram illustrating a parallel process according to an embodiment of the present invention. In this regard, when a plurality of independent tasks with no data dependency between the data processing units are to be performed, the agent (310) may determine to call the respective data processing units for the plurality of independent tasks in parallel. Here, the respective data processing units generate different types of intermediate data, and the different types of intermediate data may include geometric shape information extracted from visual data and text-based specification information retrieved from an external source.

Specifically, there may be a situation in which different types of intermediate data must be obtained simultaneously, such as when a user requests 'a model similar to this sketch, but following the specifications of a Galaxy S24'. In this case, the agent (310) may, regardless of order or simultaneously (in parallel), send a specification information request to the crawling module (334) and a 3D information request (e.g., for the user's sketch or 2D image) to the image module (332).

Subsequently, once the agent (310) receives the specification information from the crawling module (334) and all of the 3D information from the image module (332), it synthesizes the two pieces of intermediate data to ultimately generate a structured command. Through this parallel processing method, the time required to collect different types of information can be minimized.

As another example, a case may be considered where a user requests the generation of multiple designs with a single request, such as 'make five smartphones with different heights and widths.'. In this case, the agent (310) interprets the user's request and generates five independent structured commands, each with different height and width parameters. Subsequently, it may control the parallel generation of each respective CAD representation by transmitting the five structured commands to the code generation model (320). Through this parallel processing, a user can review various design drafts and develop their ideas in a short amount of time.

While the present invention has been described with reference to the preferred embodiments, it will be understood by those skilled in the art that various changes and modifications may be made without departing from the spirit and scope of the invention as set forth in the claims that follow.

1. An electronic device, comprising:
a memory comprising at least one instruction; and
at least one processor electrically connected to the memory and configured to execute the at least one instruction,
wherein the at least one processor is configured to:
analyze a type of at least one input received from a user;
select a data processing unit corresponding to each input type;
determine a calling order of the data processing unit based on at least one of an intercorrelation between each input or a priority;
invoke at least one or more data processing units according to a determined processing flow to obtain intermediate data for the at least one input received from the user; and
integrate the intermediate data to generate a structured command for generating a Computer-Aided Design (CAD) representation.

2. The electronic device of claim 1, wherein analyzing the type of the at least one input comprises:
extracting keywords from text included in the at least one input; and
identifying a format of data included therewith.

3. The electronic device of claim 1, wherein the data processing unit comprises at least one of:
an image module configured to extract 3D information from an image;
a crawling module configured to retrieve information from an external source; and
a rendering module configured to visualize a 3D model.

4. The electronic device of claim 1, wherein determining the calling order comprises:
when a data dependency exists between a plurality of data processing units, determining to provide intermediate data obtained from an execution result of a preceding data processing unit as an input to a succeeding data processing unit.

5. The electronic device of claim 4,
wherein the preceding data processing unit is the crawling module, and the succeeding data processing unit is the image module.

6. The electronic device of claim 1, wherein determining the calling order comprises:
when a plurality of independent tasks are to be performed in the absence of a data dependency between the data processing units, determining to invoke respective data processing units for the plurality of independent tasks in parallel.

7. The electronic device of claim 6,
wherein when the plurality of independent tasks comprises generating a plurality of mutually different 3D models in response to a single request from a user,
the at least one processor executes in parallel a processing flow for generating a CAD representation for each of the plurality of 3D models.

8. The electronic device of claim 6, wherein:
the respective data processing units generate different types of intermediate data; and
the different types of intermediate data comprise geometric shape information extracted from visual data and text-based specification information retrieved from an external source.

9. The electronic device of claim 1, wherein the intermediate data comprises at least one of:
geometric shape information obtained from the image module;
text-based specification information obtained from the crawling module; and
semantic information extracted from the user input text.

10. The electronic device of claim 1, wherein the structured command is a prompt provided to an artificial intelligence model for generating the CAD representation, the prompt comprising at least one of:
a target shape of the 3D model;
a numerical constraint;
part-wise relationship information; and
material information.

11. The electronic device of claim 1, wherein the structured command is generated by analyzing the at least one input according to rules or a template of a pre-configured database.

12. A method, comprising:
analyzing a type of at least one input received from a user;
selecting a data processing unit corresponding to each input type;
determining a calling order of the data processing unit based on at least one of an intercorrelation between each input or a priority;
invoking at least one or more data processing units according to a determined processing flow to obtain intermediate data for the at least one input received from the user; and
integrating the intermediate data to generate a structured command for generating a Computer-Aided Design (CAD) representation.

13. The method of claim 12, wherein the step of determining the calling order comprises:
determining a sequential processing flow when a data dependency exists between a plurality of data processing units; and
determining a parallel processing flow when a plurality of independent tasks are to be performed in the absence of a data dependency between the data processing units.

14. The method of claim 12, wherein the structured command is a prompt provided to an artificial intelligence model for generating the CAD representation, the prompt comprising at least one of:
a target shape of the 3D model;
a numerical constraint;
part-wise relationship information; and
material information.

15. A computer program recorded on a computer-readable recording medium, the computer program configured to be executed in combination with a computer to perform the method of claim 12.
